(19) United States
(12) Patent Application Publication
(10) Pub. No.: US 2026/0338996 A1
(43) Pub. Date: Oct. 29, 2026

(54) OPTICAL IMAGING DEVICE AND METHOD FOR FORMING THE SAME

(71) Applicant: VisEra Technologies Company Limited, Hsin-Chu City (TW)

(72) Inventors: Jyun-You LU, Hsin-Chu City (TW); Yueh-Ching CHENG, Hsin-Chu City (TW); Lin-Ya TSENG, Hsin-Chu City (TW)

(21) Appl. No.: 19/192,590

(22) Filed: Apr. 29, 2025

(51) Int. Cl. G02B 3/00; G03F 7/00

(52) U.S. Cl. CPC G02B 3/0018; G02B 3/0043; G03F 7/0005

(57) ABSTRACT

A method for forming an optical imaging device is provided. The method for forming an optical imaging device includes the following steps. A transparent layer is formed above a substrate. The transparent layer is patterned by using a first mask layer that has first transparent patterns to form transparent segments. A reflow process is performed on the transparent segments to form micro-lenses. An opaque layer is formed on and between the micro-lenses. The opaque layer is patterned by using a second mask layer that has second transparent patterns to form a light-shielding layer between the micro-lenses. The second transparent patterns correspond to the first transparent patterns and have the same number as the first transparent pattern. In a cross sectional view, the first width of the first transparent pattern is smaller than or equal to the second width of the corresponding second transparent pattern.

### BACKGROUND OF THE INVENTION

### Field of the Invention

The embodiments of the present disclosure relate to an optical imaging device and a method for forming the same, and in particular they relate to a method for forming an optical imaging device that may effectively improve the issue of peeling and the optical imaging device formed by using the aforementioned method.

### Description of the Related Art

Optical imaging devices (e.g., charge-coupled device (CCD) image sensors, complementary metal-oxide semiconductor (CMOS) image sensors, and so on) have been widely used in various image-capturing apparatuses such as digital still-image cameras, digital video cameras, biometric recognition systems, and the like. The light-sensing portion of an optical imaging device may be formed at each pixel, and signal electric charges may be generated according to the amount of light received in the light-sensing portion. In addition, the signal electric charges generated in the light-sensing portion may be transmitted and amplified, whereby an image signal is obtained.

Biometric recognition has been very popular in recent years. One kind of biometric recognition system is the optical fingerprint sensor. A fingerprint recognition system has an optical fingerprint sensor that takes an image of the fingerprint of a user for the purpose of authenticating the user's identity, and then decides whether or not to allow the user to access the device incorporating the fingerprint recognition system. Fingerprint recognition systems may be used for access control in mobile devices, such as cell phones, wearable electronic devices (e.g., smart watches), and tablet computers in a reliable, non-intrusive way.

Regular optical imaging devices use a light-shielding layer (e.g., black matrix) to prevent crosstalk. However, traditional methods for forming an optical imaging device of-ten cause peeling, resulting in reduced yield of the optical imaging device.

### BRIEF SUMMARY OF THE INVENTION

In the embodiments of the present disclosure, the method for forming an optical imaging device may effectively solve the problem of the light-shielding layer peeling off, thereby improving the overall yield of the optical imaging device.

An embodiment of the present disclosure provides a method for forming an optical imaging device. The method for forming an optical imaging device includes the following steps. A transparent layer is formed above a substrate. The transparent layer is patterned by using a first mask layer that has first transparent patterns to form transparent segments. A reflow process is performed on the transparent segments to form micro-lenses. An opaque layer is formed on and between the micro-lenses. The opaque layer is patterned by using a second mask layer that has second transparent patterns to form a light-shielding layer between the micro-lenses. The second transparent patterns correspond to the first transparent patterns and have the same number as the first transparent pattern. In a cross sectional view, the first width of the first transparent pattern is smaller than or equal to the second width of the corresponding second transparent pattern.

In some embodiments, the transparent layer is patterned by using a positive photoresist, while the opaque layer is patterned by using a negative photoresist.

In some embodiments, wherein in the cross sectional view, the distance between two adjacent micro-lenses is smaller than or equal to the first width or the second width, and the first width is smaller than the second width.

In some embodiments, the second width is 1.2 to 1.8 times the first width.

In some embodiments, the difference between the second width and the first width is 0.75 μm.

In some embodiments, in the cross sectional view, the distance between two adjacent micro-lenses is greater than the first width or the second width, and the first width is equal to the second width.

In some embodiments, the method for forming an optical imaging device further includes the following step. An adhesion layer is formed between the substrate and the micro-lenses.

In some embodiments, the step of patterning the opaque layer to form the light-shielding layer includes performing a soft-baking process at 60 °C.

In some embodiments, the micro-lenses are concave micro-lenses.

In some embodiments, the micro-lenses are convex micro-lenses.

In some embodiments, in the cross-sectional view, the micro-lenses have different curvature radii.

In some embodiments, in the cross-sectional view, the light-shielding layer is divided into light-shielding segments that have different widths.

In some embodiments, in the cross-sectional view, the micro-lenses are arranged asymmetrically.

An embodiment of the present disclosure provides an optical imaging device. The optical imaging device includes a substrate and micro-lenses that are disposed above the substrate. The micro-lenses are formed by using a first mask layer that has first transparent patterns. The optical imaging device also includes a light-shielding layer disposed between the micro-lenses. The light-shielding layer is formed by using a second mask layer that has second transparent patterns. The second transparent patterns correspond to the first transparent patterns and have the same number as the first transparent pattern. In a cross sectional view, the first width of the first transparent pattern is smaller than or equal to the second width of the corresponding second transparent pattern.

In some embodiments, wherein in the cross sectional view, the distance between two adjacent micro-lenses is smaller than or equal to the first width or the second width, and the first width is smaller than the second width.

In some embodiments, the second width is 1.2 to 1.8 times the first width.

In some embodiments, the difference between the second width and the first width is 0.75 μm.

In some embodiments, in the cross sectional view, the distance between two adjacent micro-lenses is greater than the first width or the second width, and the first width is equal to the second width.

In some embodiments, the optical imaging device further includes an adhesion layer disposed between the substrate and the micro-lenses.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1A to FIG. 1E are partial cross-sectional views illustrating a method for forming an optical imaging device at various stages according to some embodiments of the present disclosure.

FIG. 2A and FIG. 2B are partial cross-sectional views illustrating a method for forming an optical imaging device at various stages according to some other embodiments of the present disclosure.

FIG. 3A and FIG. 3B are partial cross-sectional views illustrating optical imaging devices according to some other embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in it-self dictate a relationship between the various embodiments and/or configurations discussed.

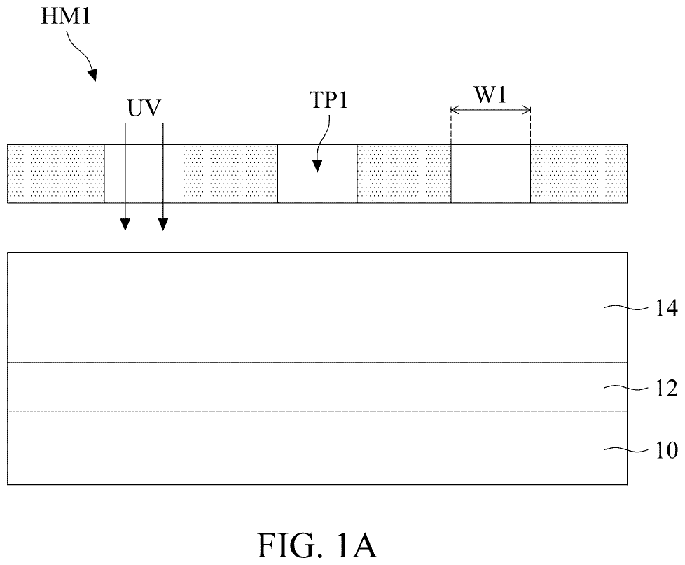

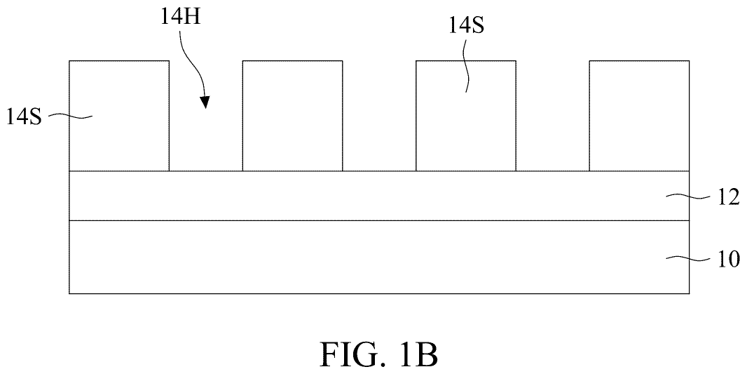

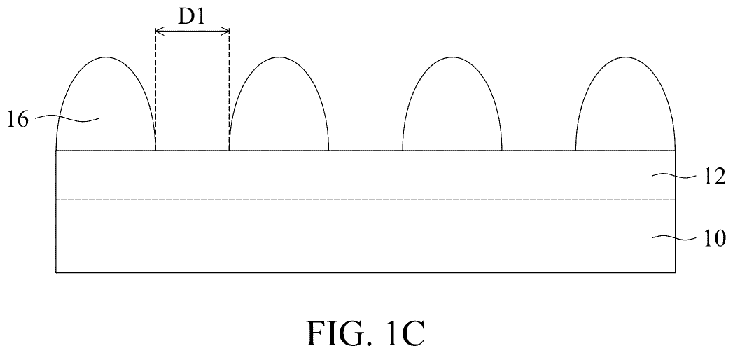

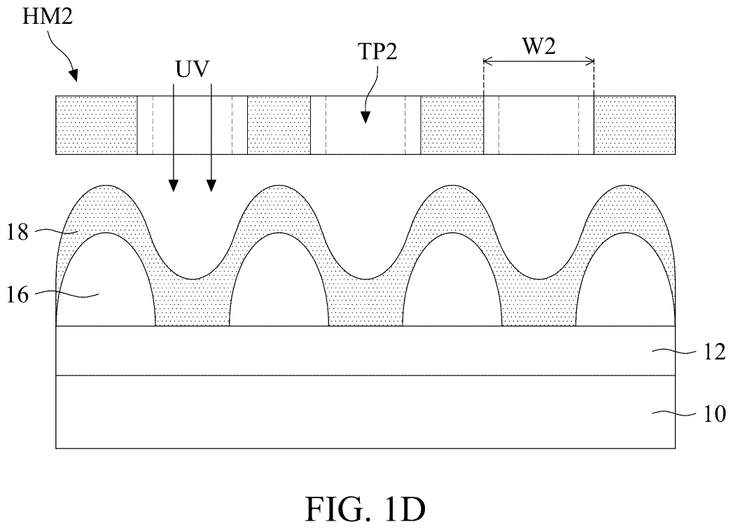

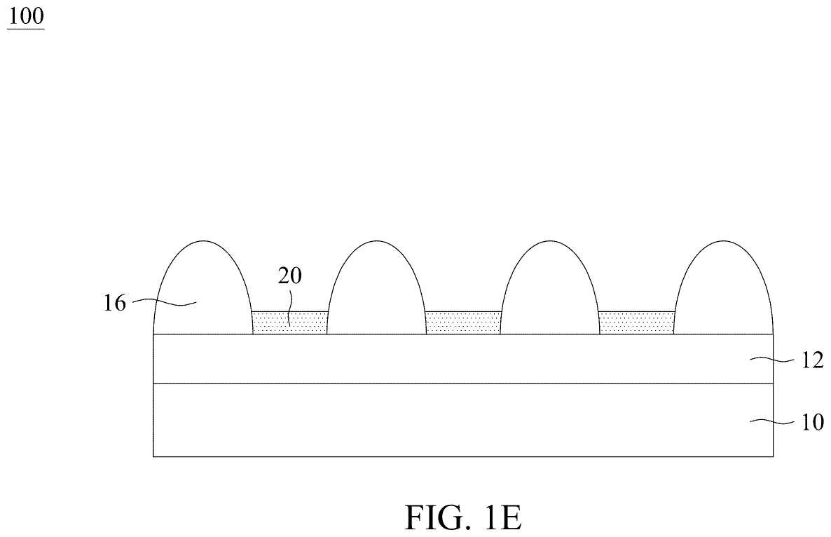

FIG. 1A to FIG. 1E are partial cross-sectional views illustrating a method for forming an optical imaging device 100 at various stages according to some embodiments of the present disclosure. It should be noted that some components of the optical imaging device 100 have been omitted in FIG. 1A to FIG. 1E for the sake of brevity.

Referring to FIG. 1A, in some embodiments, a transparent layer 14 is formed above a substrate 10. For example, the substrate 10 may include an elementary semiconductor (e.g., silicon or germanium), a compound semiconductor (e.g., silicon carbide (SiC), gallium arsenic (GaAs), indium arsenide (InAs), or indium phosphide (InP)), an alloy semiconductor (e.g., silicon germanium (SiGe), silicon germanium carbide (SiGeC), gallium arsenic phosphide (GaAsP), or gallium indium phosphide (GaInP)), any other applicable semiconductor, or a combination thereof. Moreover, the substrate 10 may be a semiconductor-on-insulator (SOI) substrate. The semiconductor-on-insulator substrate may include a bottom substrate, a buried oxide layer disposed on the bottom substrate, and a semiconductor layer disposed on the buried oxide layer. Alternately, the substrate 10 may be a semiconductor wafer (e.g., a silicon wafer, or any other applicable semiconductor wafer).

Furthermore, the substrate 10 may include various p-type doped regions and/or n-type doped regions formed by a process such as an ion implantation process and/or a diffusion process. The doped regions may be configured to form a transistor, a photodiode, and/or a light-emitting diode, but the present disclosure is not limited thereto.

Moreover, the substrate 10 may include various isolation features to separate various device regions in the substrate 10. For example, the isolation features may include a shallow trench isolation (STI) feature, but the present disclosure is not limited thereto. The formation of a shallow trench isolation (STI) feature may include etching a trench in the substrate 10 and filling in the trench with insulating materials (e.g., silicon oxide, silicon nitride, or silicon oxynitride). The filled trench may have a multi-layer structure, such as a thermal oxide liner layer with silicon nitride filling the trench. A chemical mechanical polishing (CMP) process may be performed to polish back excessive insulating materials and planarize the top surface of the isolation features.

The substrate 10 may include various conductive features (e.g., conductive lines or vias). For example, the conductive features may be made of aluminum (Al), copper (Cu), tungsten (W), an alloy thereof, any other applicable conductive material, or a combination thereof.

The transparent layer 14 may include glass, epoxy resin, silicone resin, polyurethane, any other applicable material, or a combination thereof, but the present disclosure is not limited thereto. Moreover, the transparent layer 14 may be formed by a deposition process, such as chemical vapor deposition (CVD), atomic layer deposition (ALD), molecular beam epitaxy (MBE), liquid phase epitaxy (LPE), the like, or a combination thereof.

As shown in FIG. 1A, in this embodiment, an adhesion layer 12 is formed between the substrate 10 and transparent layer 14. For example, the adhesion layer 12 may include polymer or dielectric material, but the present disclosure is not limited thereto. Moreover, the adhesion layer 12 may be formed by a deposition process. Examples of the deposition process have been mentioned above and will not be repeated here.

Referring to FIG. 1A and FIG. 1B, in some embodiments, the transparent layer 14 is patterned by using a mask layer HM1 to form multiple transparent segments 14S. As shown in FIG. 1A, the mask layer HM1 has multiple transparent patterns TP1, and the transparent pattern TP1 has a width W1 (e.g., ranging from about 1 μm to about 3 μm). In more detail, the mask layer HM1 is formed above the transparent layer 14, and then an etching process is performed to etch the transparent layer 14 using the mask layer HM1 as an etch mask.

The mask layer HM1 may include a hard mask and may include silicon oxide (SiO₂), silicon nitride (SiN), silicon oxynitride (SiON), silicon carbide (SiC), silicon car-bonitride (SiCN), the like, or a combination thereof. The mask layer HM1 may be a single-layer or a multi-layer structure. The mask layer HM1 may be formed by a deposition process, a photolithography process, any other suitable process, or a combination thereof. For example, the deposition process may include spin-on coating, CVD, ALD, the like, or a combination thereof. Moreover, the photolithography process may include photoresist coating (e.g., spin coating), soft baking, mask aligning, exposure, post-exposure baking (PEB), developing, rinsing, drying (e.g., hard baking), any other suitable process, or a combination thereof.

The etching process may include a dry etching process, a wet etching process, or a combination thereof. For example, the dry etching process may include reactive ion etch (RIE), inductively-coupled plasma (ICP) etching, neutral beam etch (NBE), electron cyclotron resonance (ERC) etching, the like, or a combination thereof. For example, the wet etching process may use, for example, hydrofluoric acid (HF), ammonium hydroxide (NH₄OH), or any suitable etchant.

In this embodiment, the transparent layer 14 is patterned by using a positive photoresist. With respect to a positive photoresist, illuminated regions of the positive photoresist (i.e., the region irradiated by ultraviolet (UV) light after passing through the transparent patterns TP1) become soluble and are removed via application of a solvent during development. Thus, a pattern formed in the positive photoresist is a positive image of opaque regions of the template between the light source and the positive photoresist. As shown in FIG. 1B, multiple holes 14H are formed between the transparent segments 14S after the etching process.

Then, referring to FIG. 1C, a reflow process is performed on the transparent segments 14S to form micro-lenses 16. In this embodiment, the micro-lenses 16 are convex micro-lenses, and in the cross-sectional view, the micro-lenses 16 are arranged symmetrically. That is, the micro-lenses 16 may have fixed pitch, but the present disclosure is not limited thereto. As shown in FIG. 1A and FIG. 1C, in this embodiment, the distance D1 between two adjacent micro-lenses 16 is smaller than or equal to the width W1 of the transparent pattern TP1.

In some other examples, the micro-lenses 16 may be micro-pyramid structures (e.g., circular cone or quadrangular pyramid), micro-trapezoidal structures (e.g., flat top cone or truncated Square Pyramid). Alternatively, the micro-lenses 16 may be gradient-index structures (not shown), but the present disclosure is not limited thereto. The shape and size of the micro-lens 16 may be adjusted according to actual needs.

Then, referring to FIG. 1D, an opaque layer 18 is formed on and between the micro-lenses 16. In more detail, the opaque layer 18 may formed on the adhesion layer 12 and between the micro-lenses 16. For example, the opaque layer 18 may include photoresist (e.g., black photoresist, or other applicable photoresist which is not transparent), ink (e.g., black ink, or other applicable ink which is not transparent), molding compound (e.g., black molding compound, or other applicable molding compound which is not transparent), solder mask (e.g., black solder mask, or other applicable solder mask which is not transparent), (black-)epoxy polymer, any other applicable material, or a combination thereof. Moreover, the opaque layer 18 may include a light curing material, a thermal curing material, or a combination thereof. As shown in FIG. 1D, the opaque layer 18 may be conformally formed on the adhesion layer 12 and between the micro-lenses 16.

Then, referring to FIG. 1D and FIG. 1E, the opaque layer 18 is patterned by using a mask layer HM2 to form a light-shielding layer 20 between the micro-lenses 16, thereby forming the optical imaging device 100. As shown in FIG. 1D, the mask layer HM2 has multiple transparent patterns TP2, and the transparent pattern TP2 has a width W2 (e.g., ranging from about 2 μm to about 4 μm). In more detail, the mask layer HM2 is formed above the opaque layer 18, and then an etching process is performed to etch the opaque layer 18 using the mask layer HM2 as an etch mask.

In this embodiment, the opaque layer 18 is patterned by using a negative photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template between the light source and the negative photoresist.

In the embodiments of the present disclosure, the transparent patterns TP2 of the mask layer HM2 correspond to the transparent patterns TP1 of the mask layer HM1 and have the same number as the transparent pattern TP1 of the mask layer HM1. That is, there are the same number of transparent patterns TP2 of the mask layer HM2 as there are transparent patterns TP1 of the mask layer HM1. Moreover, in this embodiment, in the cross sectional view, the width W1 of the transparent pattern TP1 is smaller than the width W2 of the corresponding transparent pattern TP2. In other words, the distance D1 between two adjacent micro-lenses 16 is smaller than the width W2 of the transparent pattern TP2.

In some embodiments, the width W2 of the transparent pattern TP2 is about 1.2 to about 1.8 times the width W1 of the corresponding transparent pattern TP1. In this embodiment, the difference between the width W2 of the transparent pattern TP2 and the width W1 of the corresponding transparent pattern TP1 ranges from about 0.25 μm to 1.25 μm, such as about 0.75 μm, but the present disclosure is not limited thereto.

Since the width W1 of the transparent pattern TP1 is smaller than the width W2 of the corresponding transparent pattern TP2, in the cross-sectional view, the width of the light-shielding layer 20 may be slightly greater than the distance D1 between two adjacent two micro-lenses 16, so that the light-shielding layer 20 may be stably arranged between the micro-lenses 16. Therefore, the peeling issues of the light-shielding layer 20 may be effectively improved, thereby improving the overall yield of the optical imaging device 100.

In some embodiments, the step of patterning the opaque layer 18 to form the light-shielding layer 20 further includes a step of performing a soft-baking process at about 60 °C. At this temperature, it is possible to effectively prevent the light-shielding layer 20 from remaining excessively on the micro-lenses 16 during the etching process.

As shown in FIG. 1E, in some embodiments, the optical imaging device 100 includes a substrate and multiple micro-lenses 16 that are disposed above the substrate 10. The micro-lenses 16 are formed by using the mask layer HM1 that has multiple transparent patterns TP1. The optical imaging device 100 also includes a light-shielding layer 20 that is disposed between the micro-lenses 16. The light-shielding layer 20 is formed by using the mask layer HM2 that has multiple transparent patterns TP2. The transparent patterns TP2 of the mask layer HM2 correspond to the transparent patterns TP1 of the mask layer HM1 and have the same number as the transparent patterns TP1 of the mask layer HM1. That is, there are the same number of transparent patterns TP2 of the mask layer HM2 as there are transparent patterns TP1 of the mask layer HM1. In a cross sectional view, the width W1 of the transparent pattern TP1 is smaller than the width W2 of the corresponding transparent pattern TP2.

As shown in FIG. 1E, in some embodiments, the optical imaging device 100 further includes an adhesion layer 12 disposed between the substrate 10 and the micro-lenses 16.

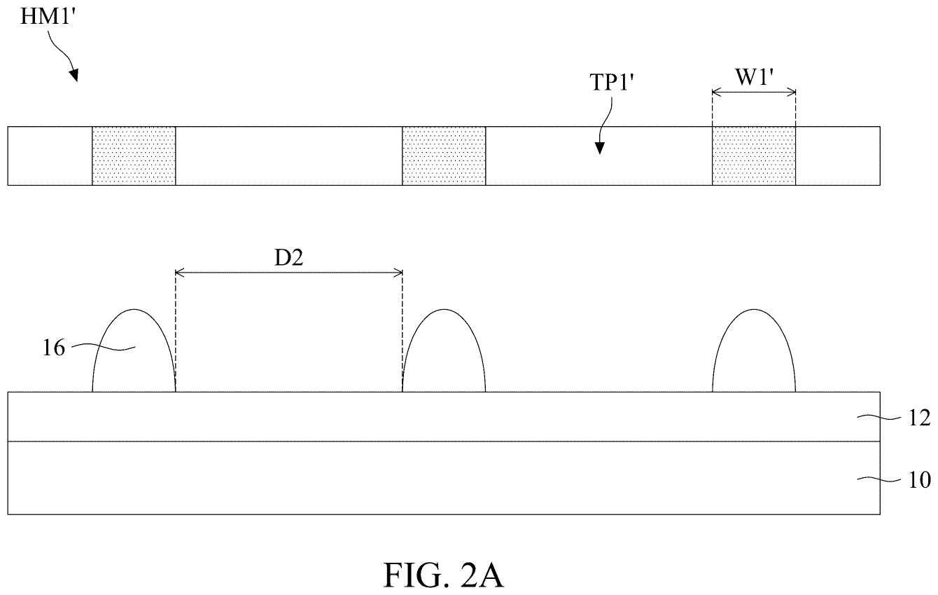

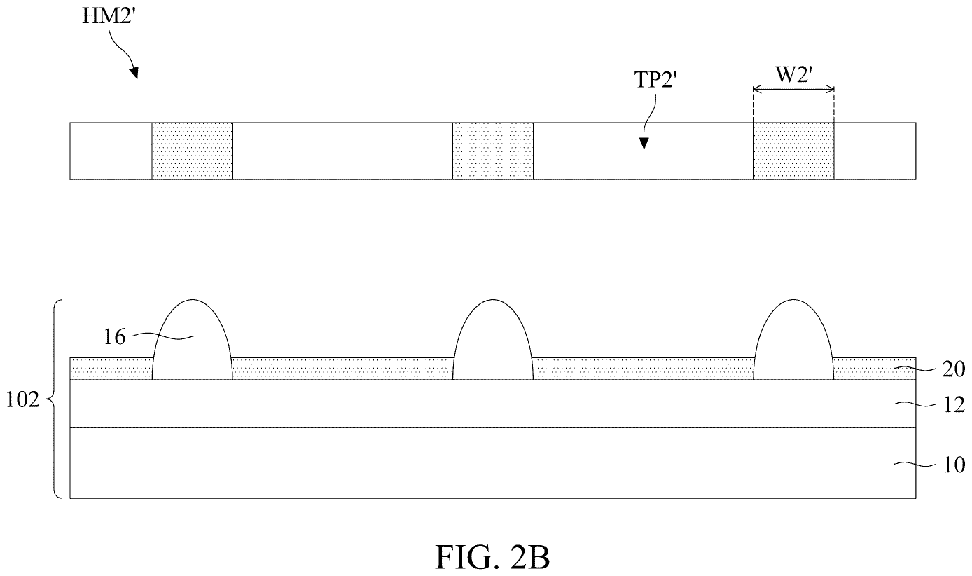

FIG. 2A and FIG. 2B are partial cross-sectional views illustrating a method for forming an optical imaging device 102 at various stages according to some other embodiments of the present disclosure. Similarly, some components of the optical imaging device 102 have been omitted in FIG. 2A and FIG. 2B for the sake of brevity.

As shown in FIG. 2A, the mask layer HM1′ has multiple transparent patterns TP1′, and the transparent pattern TP1′ has a width W1′. In this embodiment, the distance D2 between two adjacent micro-lenses 16 is greater than the width W1′ of the transparent pattern TP1′.

As shown in FIG. 2B, the mask layer HM2′ has multiple transparent patterns TP2′, and the transparent pattern TP2′ has a width W2′. In this embodiment, the width W1′ of the transparent pattern TP1′ is equal to the width W2′ of the transparent pattern TP2′. In other words, the distance D2 between two adjacent micro-lenses 16 is greater than the width W2′ of the transparent pattern TP2′. In this embodiment, the mask layer HM2′ may be the same as the mask layer HM1′.

As shown in FIG. 2B, in some embodiments, the optical imaging device 102 includes a substrate and multiple micro-lenses 16 that are disposed above the substrate 10. The micro-lenses 16 are formed by using the mask layer HM1′ that has multiple transparent patterns TP1′. The optical imaging device 102 also includes a light-shielding layer 20 that is disposed between the micro-lenses 16. The light-shielding layer 20 is formed by using the mask layer HM2′ that has multiple transparent patterns TP2′. The transparent patterns TP2′ of the mask layer HM2′ correspond to the transparent patterns TP1′ of the mask layer HM1′ and have the same number as the transparent patterns TP1′ of the mask layer HM1′. That is, there are the same number of transparent patterns TP2′ of the mask layer HM2′ as there are transparent patterns TP1′ of the mask layer HM1′. In a cross sectional view, the width W1′ of the transparent pattern TP1′ is equal to the width W2′ of the corresponding transparent pattern TP2′.

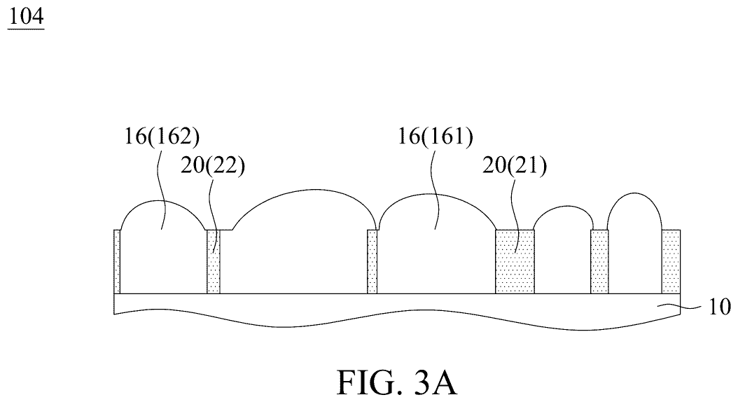

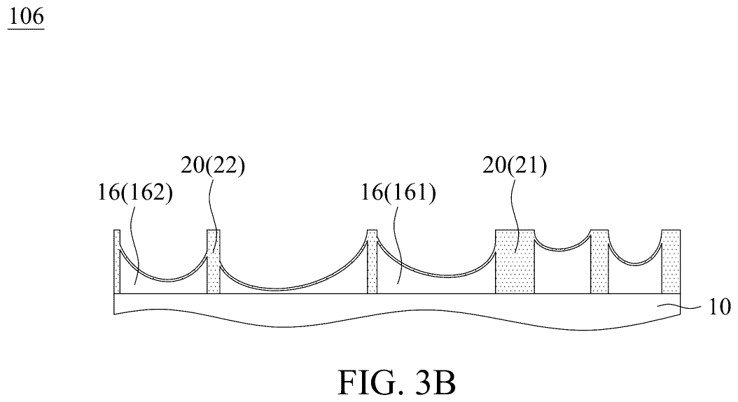

FIG. 3A and FIG. 3B are partial cross-sectional views illustrating optical imaging devices 102 and 104 according to some other embodiments of the present disclosure. Similarly, some components of the optical imaging devices 102 and 104 have been omitted in FIG. 3A and FIG. 3B for the sake of brevity.

As shown in FIG. 3A, in this embodiment, in the cross-sectional view, the optical imaging device 102 includes convex micro-lenses 16 that have different curvature radii. In more detail, the micro-lens 161 has a curvature radius different from that of the micro-lens 162. Moreover, in this embodiment, in the cross-sectional view, the light-shielding layer 20 is divided into light-shielding segments (e.g., light-shielding segments 21 and 22) that have different widths. As shown in FIG. 3A, in this embodiment, in the cross-sectional view, the micro-lenses are arranged asymmetrically due to the different sizes or curvature radii of the convex micro-lenses 16.

As shown in FIG. 3B, in this embodiment, in the cross-sectional view, the optical imaging device 104 includes concave micro-lenses 16 that have different curvature radii. In more detail, the micro-lens 161 has a curvature radius different from that of the micro-lens 162. Moreover, in this embodiment, in the cross-sectional view, the light-shielding layer 20 is divided into light-shielding segments (e.g., light-shielding segments 21 and 22) that have different widths. As shown in FIG. 3B, in this embodiment, in the cross-sectional view, the micro-lenses are arranged asymmetrically due to the different sizes or curvature radii of the concave micro-lenses 16.

As noted above, in the embodiments of the present disclosure, the method for forming an optical imaging device may effectively solve the problem of the light-shielding layer peeling off, thereby improving the overall yield of the optical imaging device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A method for forming an optical imaging device, comprising:
forming a transparent layer above a substrate;
patterning the transparent layer by using a first mask layer that has first transparent patterns to form transparent segments;
performing a reflow process to the transparent segments to form micro-lenses;
forming an opaque layer on and between the micro-lenses; and
patterning the opaque layer by using a second mask layer that has second transparent patterns to form a light-shielding layer between the micro-lenses,
wherein the second transparent patterns correspond to the first transparent patterns and have the same number as the first transparent pattern, and in a cross sectional view, a first width of one of the first transparent patterns is smaller than or equal to a second width of a corresponding one of the second transparent patterns.

2. The method for forming an optical imaging device as claimed in claim 1, wherein the transparent layer is patterned by using a positive photoresist, while the opaque layer is patterned by using a negative photoresist.

3. The method for forming an optical imaging device as claimed in claim 1, wherein in the cross sectional view, a distance between adjacent two of the micro-lenses is smaller than or equal to the first width or the second width, and the first width is smaller than the second width.

4. The method for forming an optical imaging device as claimed in claim 3, wherein the second width is 1.2 to 1.8 times the first width.

5. The method for forming an optical imaging device as claimed in claim 3, wherein the difference between the second width and the first width is 0.75 μm.

6. The method for forming an optical imaging device as claimed in claim 1, wherein in the cross sectional view, a distance between adjacent two of the micro-lenses is greater than the first width or the second width, and the first width is equal to the second width.

7. The method for forming an optical imaging device as claimed in claim 1, further comprising:
forming an adhesion layer between the substrate and the micro-lenses.

8. The method for forming an optical imaging device as claimed in claim 1, wherein the step of patterning the opaque layer to form the light-shielding layer comprises:
performing a soft-baking process at 60 °C.

9. The method for forming an optical imaging device as claimed in claim 1, wherein the micro-lenses are concave micro-lenses.

10. The method for forming an optical imaging device as claimed in claim 1, wherein the micro-lenses are convex micro-lenses.

11. The method for forming an optical imaging device as claimed in claim 1, wherein in the cross-sectional view, the micro-lenses have different curvature radii.

12. The method for forming an optical imaging device as claimed in claim 1, wherein in the cross-sectional view, the light-shielding layer is divided into light-shielding segments that have different widths.

13. The method for forming an optical imaging device as claimed in claim 1, wherein in the cross-sectional view, the micro-lenses are arranged asymmetrically.

14. An optical imaging device, comprising:
a substrate;
micro-lenses disposed above the substrate, wherein the micro-lenses are formed by using a first mask layer that has first transparent patterns;
a light-shielding layer disposed between the micro-lenses, wherein the light-shielding layer is formed by using a second mask layer that has second transparent patterns,
wherein the second transparent patterns correspond to the first transparent patterns and have the same number as the first transparent pattern, and in a cross sectional view, a first width of one of the first transparent patterns is smaller than or equal to a second width of a corresponding one of the second transparent patterns.

15. The optical imaging device as claimed in claim 14, wherein in the cross sectional view, a distance between adjacent two of the micro-lenses is smaller than or equal to the first width or the second width, and the first width is smaller than the second width.

16. The optical imaging device as claimed in claim 15, wherein the second width is 1.2 to 1.8 times the first width.

17. The optical imaging device as claimed in claim 15, wherein the difference between the second width and the first width is 0.75 μm.

18. The optical imaging device as claimed in claim 14, wherein in the cross sectional view, a distance between adjacent two of the micro-lenses is greater than the first width or the second width, and the first width equal to the second width.

19. The optical imaging device as claimed in claim 14, further comprising:
an adhesion layer disposed between the substrate and the micro-lenses.
